(19) United States
(12) Patent Application Publication
(10) Pub. No.: US 2024/0118342 A1
(43) Pub. Date: Apr. 11, 2024

(54) METHOD FOR DETERMINING A CONDITION OF AN ENERGY STORE

(71) Applicant: TWAICE Technologies GmbH, München (DE)

(72) Inventors: Devin ATUKALP, München (DE); Kilian KINK, München (DE)

(21) Appl. No.: 18/039,000

(22) PCT Filed: Nov. 26, 2021
(86) PCT No.: PCT/EP2021/083151

§ 371 Date: May 26, 2023

(30) Foreign Application Priority Data
Nov. 26, 2020 (DE) 10 2020 131 392.6

(51) Int. Cl. G01R 31/367; G01R 31/3842

(52) U.S. Cl. CPC G01R 31/367; G01R 31/3842

(57) ABSTRACT

The invention relates to a computer-implemented method for determining a state of an energy storage device. In successive iterations of a Kalman filter procedure, the process noise or measurement noise covariances are dynamically updated.

The present invention relates to a Kalman filter method for determining a state of an energy storage device, in particular a state of charge of an energy storage device; furthermore a corresponding device, a computer program, and an electronically readable data carrier are provided.

### TECHNICAL BACKGROUND

First applications of Kalman filters (KF) to estimate a state of charge (SOC) of a battery were shown in Plett, Gregory, “Extended Kalman filtering for battery management systems of LiPB-based HEV battery packs”, Journal of Power Sources, 2004. The main advantages of a KF-based SOC estimation are a higher accuracy of the SOC estimation and robustness against sensor errors.

Since their introduction in 2004, numerous adjustments and enhancements have been made to SOC Kalman filters to better address the challenges of SOC KF. Non-linearity can be efficiently handled by a variety of methods, e.g., by extended KF, sigma-point KF, and similar algorithms, which give similar results for most applications, as described, for example, in Campestrini, Christian, “Practical feasibility of Kalman filters for the state estimation of lithium-ion batteries”, dissertation Technical University of Munich, 2018.

Among the challenges critical to the accuracy of SOC estimation accuracy is providing an accurate battery model (equivalent circuit model) over the service life. The parameters of the battery model are dependent on temperature, SOC, and aging. Another remaining challenge is related to the tuning (adjustment) of the KF-noise covariances.

### SUMMARY

Therefore, there is a need for improved techniques for determining a state of charge of an energy storage device that overcome or mitigate at least some of the mentioned restrictions and disadvantages.

This object is achieved by the features of the independent claims. Further advantageous exemplary embodiments are described in the dependent claims.

The solution according to the invention is described hereinafter with respect to the claimed methods and the claimed devices, and also with respect to energy storage devices, energy systems, computer programs, data carriers, and distributed databases according to the invention. Features, advantages, or alternative exemplary embodiments can be assigned to each of the other categories, and vice versa. In other words, the claims for the device may be enhanced by features described and/or claimed in the context of the methods, and conversely the method can comprise any steps described in the context of the devices.

In a method for determining a state of an energy storage device, a state of the energy storage device is iteratively determined in successive iterations of a Kalman filter method based on a large number of measured values of current and voltage of a charging or discharging process of the energy storage device. In this case, an error term of the Kalman filter method is updated in each case in successive iterations of the Kalman filter method. An error term can be a covariance matrix, for example.

The error term of the Kalman filter method can be determined using at least one absolute value of at least one model parameter of the Kalman filter method and/or at least one absolute value of at least one measured variable of current and voltage.

At least one uncertainty of a parameter of the model can be determined using an absolute value of at least one parameter of the model and/or at least one measured variable of current and voltage.

A Kalman filter method error term can be determined using uncertainties of values of at least one parameter of a model of the Kalman filter method.

An error term of the Kalman filter method can be determined using an uncertainty of current and/or voltage of the charging or discharging process of the energy storage device.

An uncertainty can be an error, therefore an error/uncertainty described by a probability distribution, for example a variance.

An error term of the Kalman filter method can be determined using an uncertainty or uncertainties of current and/or voltage of the charging or discharging process of the energy storage device.

The model can be a process model that determines a change in current and voltage of the energy storage as a function of the iterations based on an equivalent circuit model.

The at least one parameter can be selected from a set comprising: quantization of time steps associated with the iterations of the Kalman filter method; time constant of an oscillating circuit of an equivalent circuit model of the energy storage device; resistance of an equivalent circuit model of the energy storage device; current flow in a previous iteration of the successive iterations; or current flow in a subsequent iteration of the successive iterations. It is to be understood that a specific selection/combination from the group of parameters mentioned above, or for example all of the parameters mentioned, according to the invention enable a more precise determination of the state of the energy storage device. The error term of the filter method can thus be determined using, for example, two, three, or more uncertainties of model parameters determined in one iteration, and/or uncertainties of the measured variables current/voltage.

The error term of the process model can be a covariance matrix that describes a cross-dependence of the uncertainties of process parameters of a large number of parameters of a model of the Kalman filter method. Therefore, an error term (or in other words term, or part of the equation) associated with the process model (process equation), in particular an additive term, can describe or contain the process noise (also system noise), in other words modeling errors or modeling inaccuracies, accordingly an error term associated with the measurement model (measurement equation) can describe or contain the measurement noise, i.e., measurement errors or measurement inaccuracies.

The uncertainties of the process parameters of the large number of process parameters can be modeled by probability distributions which are selected from: Gaussian normal distribution, uniform distribution, Weibull distribution.

A device for determining a state of an energy storage device comprises a computing unit, a memory unit, an interface unit, wherein the memory unit stores commands executable by the computing unit, wherein the device is designed, when the commands are executed in the computing unit, to determine a state of an energy storage device in each of successive iterations of a Kalman filter method based on a large number of measured values of current and voltage of a charging or discharging process of the energy storage device. In this case, an error term of the Kalman filter method is updated in each case in successive iterations of the Kalman filter method. In some examples, 2, 3, more, or all of the error terms of the Kalman filter method can be updated.

The disclosed techniques thus enable a more accurate determination of the state of charge of the energy storage device in that error parameters are no longer abstract and predetermined values, but are dynamically determined for each iteration directly based on the uncertainties of the individual model parameters and the sensor noise. Tuning error parameters is simpler in that only the uncertainty of model parameters and sensors has to be defined. The uncertainty of the model parameters is adjusted according to the requirements of the application: robustness vs. convergence. Uncertainties of model parameters are (normally) transferable to different battery types (for example, ±20% for R₀ independent of the battery). The sensor noise, or sensor inaccuracy, is known from sensor specifications or benchmarking experiments. In addition, the error parameters are dynamic. For example, the dynamics of the input current have an influence on the error parameters. The error parameters of system states (SOC, U_{RC}, . . . ) depend on the input I. Σ_{SOC} is a function of I(k), so higher I(k) changes SOC(k) more strongly, due to which increasing the error parameter of SOC improves accuracy.

A device, an energy storage device, and an energy system are configured to carry out any method or any combination of methods according to the present disclosure.

The device, the energy storage device, or the energy system can comprise a processor, a memory, and an interface, wherein the memory comprises commands that, when executed by the processor, cause the processor to perform the steps of any method according to the present disclosure.

A computer program comprises commands that, when executed by a processor, cause the program to perform the steps of any method according to the present disclosure.

An electronically readable data carrier comprises commands that, when executed by a processor, cause it to perform the steps of any method according to the present disclosure. For example, the data and commands for executing the method according to the invention and/or the measurement data can be stored in a distributed database, in particular a cloud.

Technical effects can be achieved for such devices, energy storage devices, energy systems, computer programs, cloud solutions, and electronically readable data carriers, which correspond to the technical effects for the device according to the present disclosure.

Although the features described in the summary above and the following detailed description are described in the context of specific examples, it is to be understood that the features can be used not only in the respective combinations, but also can be used in isolation or in any combination, and features from different examples of devices, methods, energy storage devices, and energy systems can be combined with one another and correlate with one another unless expressly stated otherwise.

Therefore, the summary above is intended to provide only a brief overview of some features of some embodiments and implementations and is not to be understood as a restriction. Other embodiments can comprise features other than those described above.

### BRIEF DESCRIPTION OF THE DRAWINGS

The invention is explained in more detail below using preferred exemplary embodiments with reference to the accompanying drawings.

The same reference signs denote the same or similar elements in the figures. The figures are schematic representations of various exemplary embodiments of the invention, wherein the elements shown in the figures are not necessarily illustrated to scale. Rather, the various elements shown in the figures are presented in such a way that the function and general purpose thereof can be understood by one skilled in the art.

FIG. 1 schematically shows an SOC determination accuracy based on a known Kalman filter as a function of temperature and service life.

FIG. 2 schematically shows an equivalent circuit model in the form of an RC model having i RC circuits according to exemplary embodiments of the invention.

FIG. 3 shows a flow chart having steps of a Kalman filter for determining a state of charge of an energy storage device, according to exemplary embodiments of the invention.

FIG. 4 schematically shows a device which is configured to determine a state of charge of an energy storage device by means of a method according to the invention.

### DETAILED DESCRIPTION

The properties, features, and advantages of this invention described above, and the manner in which they are achieved, will become clearer and more easily understandable in connection with the following description of the exemplary embodiments, which are explained in more detail in connection with the figures.

It is to be noted that the description of the exemplary embodiments is not to be understood in a restrictive sense. The scope of the invention is not to be restricted by the exemplary embodiments described below or by the figures, which are for illustration only.

Various techniques for determining a state of charge of an energy storage device are described in more detail below.

Unless otherwise specified in the following description, the terms calculate, determine, generate, configure, filter, and the like preferably refer to acts and/or processes and/or processing steps that modify and/or generate data and/or convert the data into other data, wherein the data can be represented or present in particular as physical variables, for example as electrical pulses. In particular, the terms computer, control device, or device are to be interpreted as broadly as possible in order to cover in particular all electronic devices having data processing properties. Computers can thus be, for example, personal computers, servers, programmable logic controllers (PLCs), handheld computer systems, Pocket PC devices, IoT devices, mobile radio devices and other communication devices, cloud applications, processors, and other electronic devices for data processing, i.e., which can process data with computer support.

The first application of Kalman filters (KF) to estimate a state of charge (SOC) of a battery was shown by Plett, for example, in Plett, Gregory, “Extended Kalman filtering for battery management systems of LiPB-based HEV battery packs”, Journal of Power Sources, 2004. The main advantages of the KF-based SOC estimation are higher accuracy of the SOC estimation and robustness against sensor failures.

Since the introduction in 2004, numerous adjustments and enhancements have been made to SOC Kalman filters to better address the challenges of SOC KF. Nonlinearity can be efficiently handled by a variety of methods, for example by extended KF, sigma-point KF, and similar algorithms, which yield similar results for most applications.

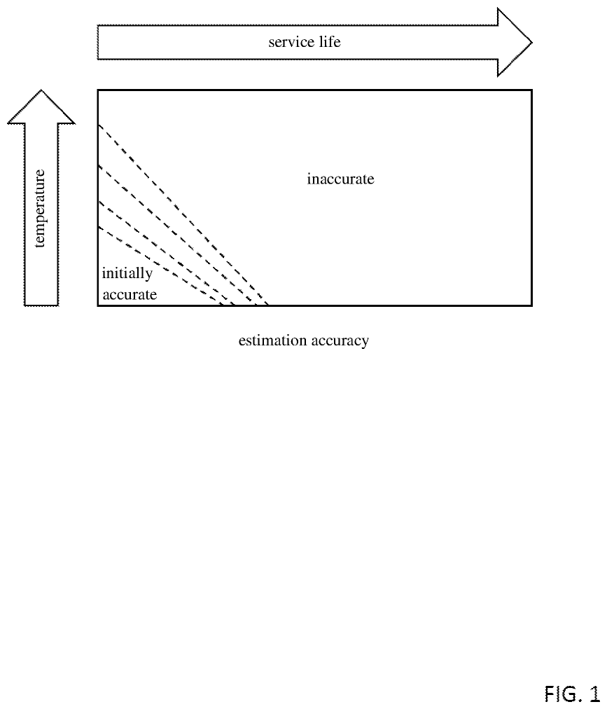

FIG. 1 schematically shows an SOC estimation accuracy based on a conventional Kalman filter as a function of temperature and service life.

Among the challenges critical to the accuracy of SOC estimation accuracy is providing an accurate battery model (equivalent circuit model) over the service life. The parameters of the battery model are dependent on temperature, SOC, and aging. Thus, even if a perfect model for the beginning of life (BoL) is provided, its accuracy decreases over the battery service life, due to which the KF-SOC estimation accuracy is reduced. As shown in FIG. 1, the expected accuracy of a SOC-KF worsens with the service life and temperature. It is to be noted here that the battery model used by the SOC KF is parameterized for a limited temperature range at BoL, which is identified by “Init”. Another remaining challenge is related to the tuning (adjustment) of the KF-noise covariances.

A brief summary of a general nonlinear extended Kalman filter is provided hereinafter, as described in the lecture notes for course ECE5720: Battery Management and Control by Gregory Plett, 2015, University of Colorado.

The nonlinear state space model is provided

xₖ=f(xₖ₋₁,uₖ₋₁,wₖ₋₁)

yₖ=h(xₖ,uₖ,vₖ),
wherein the error terms wₖ and vₖ are independent Gaussian error terms having covariance matrices Σ_{\tilde{w}} and Σ_{\tilde{v}}, respectively.

The following definitions also apply:

$${{\hat{A}}_{k} = \frac{df ( {x}_{k} , {u}_{k} , {w}_{k} )}{d {x}_{k}} \vert}_{{x}_{k} = {\hat{x}}_{k}^{+}}$$

$${{\hat{B}}_{k} = \frac{df ( {x}_{k} , {u}_{k} , {w}_{k} )}{d {w}_{k}} \vert}_{{w}_{k} = {\overline{w}}_{k}}$$

$${{\hat{C}}_{k} = \frac{dh ( {x}_{k} , {u}_{k} , {v}_{k} )}{d {x}_{k}} \vert}_{{x}_{k} = {\hat{x}}_{\overline{k}}}$$

$${{\hat{D}}_{k} = \frac{dh ( {x}_{k} , {u}_{k} , {v}_{k} )}{d {v}_{k}} \vert}_{{v}_{k} = {\overline{v}}_{k}}$$

Initialization:
For k=0 set

\hat{x}₀⁺= [symbol] [x₀]

Σ_{x,0}⁺= [symbol] [(x₀−\hat{x}₀⁺)(x₀−\hat{x}₀⁺)^{T}]

Calculation:
For k=1, 2, . . . calculate:

State Estimation Time Update:

\hat{x}ₖ⁻=f(\hat{x}ₖ₋₁⁻,uₖ₋₁,w̅ₖ₋₁)

Error Covariance Time Update:

Σ_{\tilde{x},k}⁻=Âₖ₋₁Σ_{\tilde{x},k-1}⁺Âₖ₋₁^{T}+\hat{B}ₖ₋₁Σ_{\tilde{w}}\hat{B}ₖ₋₁^{T}

Output Estimation:

ŷₖ⁻=h(\hat{x}ₖ⁻,uₖ,v̅ₖ)

Estimate Profit Matrix:

Lₖ=Σ_{\tilde{x},k}⁻Ĉₖ^{T}[ĈₖΣ_{\tilde{x},k}⁻Ĉₖ^{T}+\hat{D}ₖΣ_{\tilde{v}}\hat{D}ₖ^{T}]⁻¹

State Estimation Measurement Value Update:

\hat{x}ₖ⁺=\hat{x}ₖ⁻+Lₖ(yₖ−ŷₖ)

Error Covariance Measurement Update:

Σ_{\tilde{x},k}⁺=(I−LₖĈₖ)Σ_{\tilde{x},k}⁻

In the KF framework, the error terms (process noise covariance matrix & measurement noise covariance matrix) capture modeling errors and sensor noise. This means that a process model having a corresponding error term and a measurement model having a corresponding error term are taken into consideration. Conventionally, constant noise covariances are used, wherein the process noise covariance matrix Σ_{\tilde{w}}=constant and the measurement noise covariance matrixΣ_{\tilde{v}}=constant.

Values for constant noise covariances are, for example, set manually as described in Plett, Gregory L. Battery management systems, Volume II: Equivalent-circuit methods, Artech House, 2015, or optimized by searching for the noise covariance parameter set which minimizes the SOC estimation error, as described in Wassiliadis, Nikolaos, et al. “Revisiting the dual extended Kalman filter for battery state of charge and state of health estimation: A use-case life cycle analysis”, in Journal of Energy Storage 19, 2018.

The present disclosure is based on the finding that constant error parameters cannot ensure an SOC estimation under all conditions. Constant error parameters, when properly tuned, represent a “compromise” for the conditions to which they were tuned (e.g., SOC range, temperature range, dynamics of the input current, etc.). For example, constant error parameters which were tuned for the best SoC estimation accuracy for electronic vehicle (EV) conditions are not necessarily the best error parameters for power tool conditions. Instead of having one “generalized” individual process error parameter per system state, which has to cover all uncertainty sources, it is shown here that the process error parameters can be broken down to the uncertainty sources.

Therefore, the present disclosure addresses the challenge of ensuring higher SOC estimation accuracy over the battery service life by providing a method for tuning a battery-based SOC Kalman filter. The concept is explained using an example of a SOC-KF with an equivalent circuit model for the battery. The equivalent circuit model is designed as an RC model. However, it is to be understood that the principle can be applied to any other (battery) model.

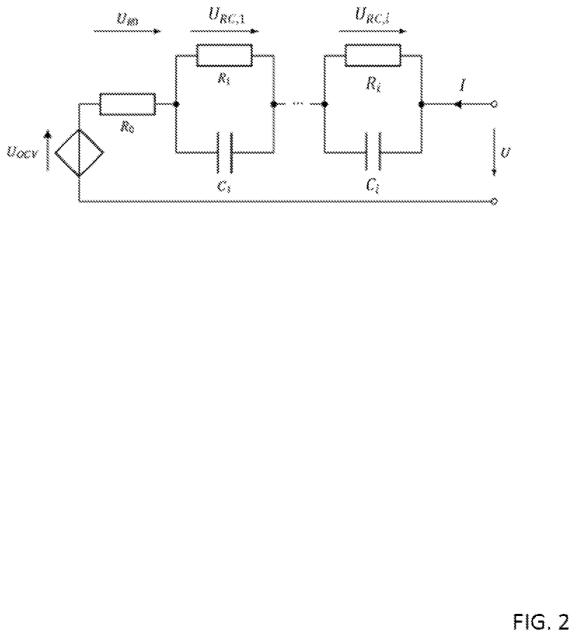

FIG. 2 schematically shows an equivalent circuit model in the form of an RC model having i RC circuits according to exemplary embodiments of the invention.

State space model for an RC model:

xₖ=f(xₖ₋₁,uₖ₋₁,wₖ₋₁)(process function)

yₖ=h(xₖ,uₖ,vₖ)(measurement function)
wherein for the RC model xₖ=[U_{RC,1}(k), . . . U_{RC,1}(k), SOC(k)] and uₖ=[I(k)] or xₖ₋₁=[U_{RC,1}(k−1), . . . , U_{RC,i}(k−1), SOC(k−1)] and uₖ₋₁=[I(k−1)].

Process Function:

$$[ \begin{matrix}{U}_{RC , 1} ( k ) \\ … \\ {U}_{RC , i} ( k ) \\ SOC ( k )\end{matrix} ] = [ \begin{matrix}\begin{matrix}exp ( - dt / {τ}_{1} ) \cdot {U}_{RC , 1} ( k - 1 ) + \\ {R}_{1} \cdot [ 1 - exp ( - dt / {τ}_{1} ) I ( k - 1 )\end{matrix} \\ … \\ \begin{matrix}exp ( - dt / {τ}_{i} ) \cdot {U}_{RC , i} ( k - 1 ) + \\ {R}_{i} \cdot [ 1 - exp ( - dt / {τ}_{1} ) I ( k - 1 )\end{matrix} \\ SOC ( k - 1 ) + dt / {C}_{N} \cdot I ( k - 1 )\end{matrix} ]$$

Measurement Function:

U(k)=U_{OCV}(SOC(k))+R₀·I(k)+U_{RC,1}(k)+ . . . +U_{RC,i}(k)

Measurement (y):
U Supply voltage

Input Signal (u):
I Current

States (x):
U_{RC,i} Voltage across the i-th RC circuit (overvoltage)
SOC state of charge

Time Step
dt

Model Parameters
U_{OCV} OCV-SOC relationship
R₀ Ohmic resistance
τᵢ Time constant of the i-th RC circuit
Rᵢ Resistance of the i-th RC circuit (dynamic resistance)
C_{N} Battery charge capacity

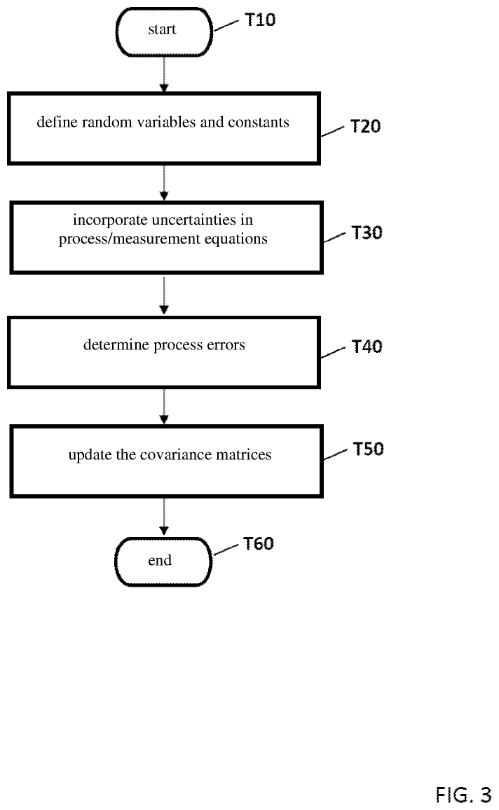

FIG. 3 shows a flow chart having steps for determining a state of charge of an energy storage device, according to exemplary embodiments of the invention.

The method begins in step T10.

In step T20, random variables and constants are defined.

This step defines which arguments of the process and measurement equations contain uncertainty. This is how the sources of uncertainty are broken down. The input (current, voltage) and the model parameters contain a certain degree of uncertainty (random variables), for example described by variances. For the sake of completeness, we also assume that the step time has an uncertainty. In this example, we assume that the random variables are normally distributed. For normal distributions, the expected value of the random variables is the mean and the uncertainty is quantified using the variance. Therefore, each random variable is assigned a variance. However, the uncertainty can also similarly be represented by various other distributions (normal, uniform, Weibull, etc. . . . ). It is to be understood that one or more parameters, at least one parameter, can have an uncertainty which, according to the invention, can be used in a dynamic update of an error term (covariance matrix) in the model.

The random variables are described below.

The inputs I(k) and I(k−1) with var(I(k))=var(I(k−1))=var(I) capture the uncertainty of the input current, which can describe the current sensor noise, for example. Note that the uncertainty has been assumed to be constant over time.

The model parameters can also have uncertainties, as described below.

The time steps dt can occur at varying time intervals. Thus, the variance of the time step (also called jitter) can be described with var(dt).
U_{OCV} with var(U_{OCV}) captures the uncertainty of the OCV-SOC relationship.
R0 with var(R0) captures the uncertainty of ohmic resistance.
τi with var(τi) captures the uncertainty of the time constant of the i-th RC circuit.
Ri with var(Ri) captures the uncertainty of the resistances of the i-th RC circuit.
CN with var(CN) captures the uncertainty of the (battery) charge capacity.

The constants are described below.

The uncertainty of the states is already taken into consideration in the state covariances of the Kalman filter. In order to calculate solely the process and measurement uncertainties, we neglect the uncertainty of the state variables SOC(k), SOC(k−1) and U_{RC,i}(k) and U_{RC,i}(k−1).

In step T30, uncertainties are introduced into process/measurement equations.

Process Function:

$${\sum }_{RC , i} = var \{ exp ( - \frac{d t}{{τ}_{i}} ) \cdot {U}_{R C , i} ( k ) + {R}_{i} [ 1 - exp ( - \frac{d t}{{τ}_{i}} ) ] \cdot I \}$$

with var(dt), var(τi), var(Rᵢ), var(I)

$${\sum }_{SOC} ( k ) = var ( \frac{d t}{{C}_{N}} \cdot I )$$

with var(dt), var(C_{N}), var(I)

Measurement Function:

Σ_{U}(k)=var(U_{OCV}+R₀·I)
with var(U_{OCV}), var(R₀), var(I)

Two approaches (option 1: calculate/estimate analytically, option 2: approximate with a simulation) for determining the uncertainty or covariance are described below.

In step T40, process errors are determined.

Option 1: calculate/estimate analytically

The following relationships can be used to calculate the covariance:

var(A+B)=var(A)+var(B)+2*covar(A,B);
var(A+B)=var(A)+var(B) assuming that A and B are independent;
var(cA+dB)=c² var(A)+d² var(B)+2cd*covar (A, B), wherein c and d are constants;
var(A*B)=E(A)²*var(B)+E(B)²*var(A)+var(A)*var(B) assuming independence;
wherein
E(A) or E(B) expectation value of A or B, which in this case can be absolute values of model parameters of the Kalman filter method and/or measured variables of current and/or voltage;
var(A) or var(B) variance of A or B, which in this case can be the uncertainty of a model parameter of the Kalman filter method and/or the uncertainty of the measured variables of current and/or voltage; and
covar (A, B) Covariance of A and B, which in this case can be the covariance of the uncertainties of a model parameter of the Kalman filter method, and/or the covariance of the uncertainty of the measured variables of current and/or voltage.

Due to the relationships listed above, the resulting covariance matrix can be determined using at least one absolute value of at least one model parameter of the Kalman filter method, and/or at least one uncertainty of a model parameter of the Kalman filter method, and/or at least one measured variable of current and/or voltage, and/or an uncertainty of the measured variables of current and/or voltage.

In some examples, one or more uncertainties of model parameters can be assumed to be zero.

In some examples, one or more of the mentioned variables can be determined by a simulation.

In some examples, functions can be linearized to approximate a resulting variance.

Approximating the variance of a function is described at https://en.wikipedia.org/wiki/Variance as follows.

In some examples, a delta method uses second-order Taylor expansions to approximate the variance of a function of one or more random variables: see Taylor expansions for the moments of functions of random variables. For example, the approximate variance of a function of one variable is given by

Var[f(X)]≈(f′(E[X]))² Var[X]

provided that f is twice differentiable and that the mean and the variance of X are finite.

Option 2: approximate with a simulation

Monte Carlo Method

For random variables, a number of values representing the uncertainty (particles) can be generated. The particles are then propagated through the equations. The more particles used, the better the distribution is represented (Monte Carlo method).

Unscented Transform

A distribution having a finite number of particles (called sigma points) can be approximated using unscented transform methods. This approach has the advantage of reducing the computational effort by avoiding a large number of particles.

In step T50 the noise covariance matrices are updated.

The resulting process-noise covariance matrix Σ_{\tilde{w}} is:

$${\sum }_{\tilde{w}} ( k - 1 ) = [ ( \begin{matrix}{\sum }_{RC , 1} ( k - 1 ) & … & 0 \\ ⋮ & ⋱ & ⋮ \\ 0 & … & {\sum }_{RC , i} ( k - 1 ) \\ & 0 & \end{matrix} ) \begin{matrix}0 \\ {\sum }_{SOC} ( k - 1 )\end{matrix} ]$$

The resulting measurement-noise covariance matrix Σ_{\tilde{v}} is:

Σ_{\tilde{v}}(k)=[Σ_{U}(k)]

In summary Σ_{\tilde{w}} and Σ_{\tilde{v}} are functions of dt, var(dt), τᵢ, var(τᵢ), C_{N}, var(C_{N}), Rᵢ, var(Rᵢ), I(k), I(k−1), and var(I).

The method ends in step T60.

In general, the process and measurement covariances are a function of the step time (step time variance), the model parameters, the model parameter variance, the input, and the input variance. In this context, the covariance matrix can be understood as the error term of the Kalman filter method, and the variances of the model parameters and/or the variances of the measured variables current or voltage can be understood as uncertainties in the corresponding arguments. Thus, the uncertainties of the Kalman filter can be dynamically redetermined in each step, for example based on corresponding values of the relevant parameters in previous iterations and/or the current iteration of the filter method.

In some examples, error terms of the Kalman filter method can thus be understood as one or more of:

| | |
|---|---|
| Σ_{\tilde{w}} | Process noise covariance matrix |
| Σ_{\tilde{v}} | Measurement noise covariance matrix |
| Σ_{\tilde{w}}, Σ_{\tilde{v}} | Noise covariance matrix |
| Σ_{\tilde{x}} | Covariance matrix (the error of \hat{x}) |
| Σ_{\tilde{w}}, Σ_{\tilde{v}}, Σ_{\tilde{x}} | Covariance matrix |

Thus, the SOC-KF tuning is more robust in relation to different operating conditions in that the parameters of the process errors are related to model parameter uncertainty (e.g., modeling errors, change of parameters due to aging) and to input uncertainty (for example sensor noise).

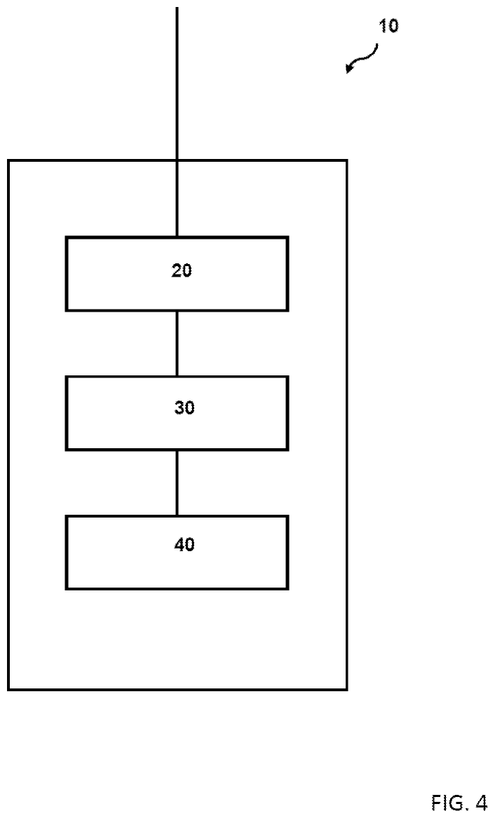

FIG. 4 schematically shows a device which is configured to determine a state of charge of an energy storage device by means of a method according to the invention.

The device 10 comprises an interface 20 for sending/receiving data, a memory 30, and a processor 40, wherein the memory 30 comprises commands which, when executed by the processor 40, cause it to carry out the steps of any Kalman filter method according to the present disclosure.

In connection with the invention, a processor can be understood as, for example, a machine or an electronic circuit. A processor can in particular be a central processing unit (CPU), a microprocessor or a microcontroller, for example an application-specific integrated circuit or a digital signal processor, possibly in combination with a memory unit for storing program commands, etc. A processor can, for example, also be an IC (integrated circuit), in particular an FPGA (field programmable gate array) or an ASIC (application-specific integrated circuit), or a DSP (Digital Signal Processor), or a GPU (Graphics Processing Unit). A processor can also be understood as a virtualized processor, a virtual machine, or a soft CPU. It can also be a programmable processor, for example, which is equipped with configuration steps for executing the mentioned method according to the invention or is configured using configuration steps in such a way that the programmable processor implements the features according to the invention of the method, the components, the modules, or other aspects and/or partial aspects of the invention.

A memory, a memory unit or memory module, and the like can be understood in connection with the invention, for example, as a volatile memory in the form of random access memory (RAM) or a permanent memory such as a hard disk or a data carrier.

In general, examples of the present disclosure provide a variety of circuits, data memories, interfaces, or electrical processing devices, for example processors. All references to these units and other electrical devices and the functions they provide are not limited to what is illustrated and described. While specific designations can be assigned to the various circuits or other disclosed electrical devices, these designations are not intended to restrict the functional scope of the circuits and the other electrical devices. These circuits and other electrical devices can be combined and/or separated from one another depending on the type of electrical embodiment desired. It is to be understood that any disclosed circuit or other electrical device can comprise any number of microcontrollers, graphics processing units (GPU), integrated circuits, memory devices such as FLASH, random access memory (RAM), read only memory (ROM), electrically programmable read only memory (EPROM), electrically erasable programmable read only memory (EEPROM), or any other suitable embodiments thereof, as well as software, which cooperate with one another to carry out the method steps disclosed herein. Additionally, each of the electrical devices can be configured to execute program code contained in an electronically readable medium and configured to perform any number of steps according to the methods of the present disclosure.

Some general conclusions can be drawn from the statements above:

The techniques disclosed relate to storage devices for electrical energy, or in other words energy storage devices chargeable by electrical energy (electricity), electrical energy storage devices, batteries, or rechargeable batteries, in particular lithium-ion batteries. However, it is to be understood that the described Kalman filter methods can be applied to any general technical system and for determining any system state. One or more filter methods can be applied at cell, module, pack, and system level.

For example, the disclosed techniques can relate to determining system states of energy storage devices or energy storage systems, for example of vehicles, aircraft, mobile or handheld electrical devices, in particular electrically driven automobiles, but also, for example, mobile electrical communication devices.

System states can comprise, for example, a state of charge (SOC), a state of health or state of aging (SOH), i.e., a present capacity, or the like. In some examples, the estimation can comprise estimating the state of charge using dynamic error limits, or estimating the available discharge/charge power of the energy storage device, or tracking changing energy storage parameters, such as a maximum available capacity and thus a quantitative estimation of the state of health of an energy storage device. Accordingly, the techniques can be applied during a charging or discharging process of an energy storage device.

For example, the device can be configured to receive and/or store measured values of a charging/discharging process. The measured values of a charging/discharging process can be stored in a memory or read from a memory, for example in a cloud, in a distributed database, in a central memory of an energy system, or locally in a memory of the energy storage device, or locally in a memory of the device. The measured values can be captured by one or more sensors, which can be arranged on the energy storage device itself, or a charging device of the energy storage device, or a consumer of the energy storage device, or in general can be connected between the energy storage device and the energy consumer. The measured values can in particular comprise a time series of successive measured values of the current, the voltage, or a temperature during the charging/discharging process.

The device can also furthermore be configured, for example, to carry out the charging/discharging process on an energy storage device. The device can be configured to comprise, measure, and/or store a current, a voltage, and a temperature of the energy storage device over time, i.e., as a measurement curve or a time profile of measurement points, during a charging/discharging process. The device can be configured to determine a charging/discharging process of the energy storage device. The device can furthermore be configured to determine a beginning and/or an end of a charging/discharging process, in other words to determine the performance of a charging/discharging process in order to determine the measurement data based thereon.

In connection with the invention, computer-based or computer-implemented can be understood, for example, as an implementation of the method in which in particular a processor executes at least one method step of the method.

In the context of the invention, comprising, in particular with regard to data and/or measurement data and/or parameters, can be understood, for example, as (computer-based) storage of a corresponding item information or a corresponding datum in a data structure/data set (which, for example, is in turn stored in a memory unit).

Providing, in particular with regard to data and/or information, can be understood in connection with the invention as computer-based providing, for example. The provision takes place, for example, via an interface (e.g., a database interface, a network interface, an interface to a memory unit). Corresponding data and/or information can be transmitted and/or sent and/or retrieved and/or received via this interface, for example when it is provided.

Measured values of a charging process or a discharging process of an energy storage device can characterize the charging/discharging process in which electrical energy is supplied to/removed from the energy storage device. For example, measured values can comprise one or more regularly sampled current or voltage values from a current or voltage curve which were measured by one or more sensors. For example, during a charging process, the current or the voltage, in other words a time profile of these measured variables, can be measured and recorded/stored by one or more sensors on the energy storage device or a charging energy source or consumer.

The device can be configured to provide an energy storage device state, i.e., a system state of the energy storage device, such as a present state of charge or a present energy storage device capacity. The present state of charge can be output, for example, as a percentage of its maximum value or as an absolute value.

The techniques disclosed can relate to Kalman filter methods. Therefore, the techniques can be methods for iterative estimation of (parameters for describing) system states, in particular on the basis of erroneous measurements.

Various examples can relate to a Kalman filter for linear and/or non-linear stochastic systems. Various examples can apply to any Kalman filter type, such as extended Kalman filter (EKF), unscented Kalman filter (UKF), sigma-point Kalman filter, fading Kalman filter (FKF), strong tracking cubature extended Kalman filter (STCEKF), multirate strong tracking extended Kalman filter (MRSTEKF), lazy extended Kalman filter (LEKF), or any other Kalman filter type.

Various examples relate to an adaptive Kalman filter, wherein a covariance matrix of the Kalman filter, in other words an error term of the Kalman filter method, is determined or updated in each of at least two successive iterations. Various examples relate to determining a system state using multidimensional probability distributions, for example probability distributions of possible errors around each estimated value, and/or probability distributions of possible errors of measured values, and/or probability distributions of possible errors of model parameters and/or model variables, and thus also correlations between the estimation errors of different variables. Using these items of information, the previous estimated values are optimally combined with the new measurements in each time step, so that remaining errors of the filter state are minimized as quickly as possible. The present filter status from estimated values, error estimates, and correlations forms a kind of memory for all the items of information obtained so far from past measured values. After each new measurement, the Kalman filter improves the previous estimated values and updates the associated error estimations and correlations. In contrast to known FIR and IIR filters of signal and time series analysis, the techniques disclosed are based on modeling, in which an explicit distinction is made between the dynamics of the system state (process model) and the process of its measurement (measurement model).

The disclosed filter methods can thus take into consideration dynamically changing parameters, i.e., system variables, and can therefore comprise at least one mathematical model in order to take into consideration dynamic relationships between the system variables. In various examples, the methods can comprise a process model and/or a measurement model. In various examples, the disclosed methods can determine system states in real time. Model parameters can be understood to mean, for example, OCV, R, RC. Current I and voltage U cannot be understood as model parameters in examples. It is to be understood that the uncertainties of the model parameters can change from iteration to iteration of the Kalman filter method and can therefore be redetermined. In some examples, an uncertainty of the at least one model parameter of the Kalman filter method can be determined using an absolute value of at least one parameter of a model and/or at least one measured variable of current and voltage of the Kalman filter method.

A covariance matrix, in other words an error term of the Kalman filter method, can be redetermined in each of at least two consecutive iterations of the Kalman filter method using a process model and/or a measurement model.

In general, therefore, an error term in the process model (process equation) can describe or contain the process noise (also system noise), i.e., modeling error, correspondingly an error term in the measurement model (measurement equation) can describe or contain the measurement noise, i.e., measurement error. Within a Kalman filter method, the process model can be used to model a state of the system based on a previous state of the system. The error term can therefore comprise a term that expresses an uncertainty in the accuracy of the process or measurement model, which is represented by process or measurement noise. In other words, the error term can comprise a term in the process equation that can depict the process noise, i.e., inaccuracies in the modeling by the process equation, i.e., it can describe or include inaccuracies or errors in the calculation or modeling of the system (model inaccuracies), and can thus differ from the error term for the estimation of the system state. Accordingly, a term in the measurement equation can describe or include the inaccuracies of the measurements.

The disclosed techniques comprise, for example, dynamically determining or updating variances, in particular using variances of the process parameters determined at the time of updating, i.e., the parameters in the process model. Using can comprise, for example, determining dependent on, and/or using and/or based on process parameters, and/or probability distributions of (values of) process parameters, and/or error terms of process parameters, which, for example, are at least partially determined from previous iterations of the Kalman filter method. An error term in the process model can be an additive error term.

Kalman filters work with Gaussian distributions. Other distributions can, for example, be mapped with a Gaussian distribution and thus deliver comparably good results in Kalman filters. It is also conceivable to use other probability distributions directly, for example a Weibull or a uniform distribution, having corresponding parameters or error terms that characterize or define these uncertainties. In this context, a variance can generally be understood as an uncertainty of a model parameter or a measured value, and a covariance matrix can be understood as an error term of the Kalman filter method.

The measurement data and/or parameters and/or the models can be stored in a cloud or in general in a network application. The methods and filters can be implemented in a cloud or a distributed database.

A network application can, for example, be understood as a decentralized distributed database, a distributed database system, a distributed database, a peer-to-peer application, a distributed memory management system, a blockchain, a distributed ledger, a distributed memory system, a distributed ledger technology (DLT) based system (DLTS), an audit-proof database system, a cloud, a cloud service, a block chain in a cloud, or a peer-to-peer database. For example, a network application (or also designated as a network application) can be a distributed database system that is implemented, for example, by means of a block chain or a distributed ledger. For example, different implementations of a block chain or a DLTS can also be used, such as a block chain or a DLTS that is implemented by means of a Directed Acrylic Graph (DAG), a cryptographic puzzle, a hash graph, or a combination of the implementation variants mentioned. A distributed database system or a network application can also be understood, for example, as a distributed database system or a network application, of which at least a part of its nodes and/or devices and/or infrastructure are implemented by a cloud. For example, the corresponding components are implemented as nodes/devices in the cloud (for example as a virtual node in a virtual machine).

The device can be, for example, a charging device for charging the energy storage device using electrical energy, a control device, for example in an energy system for controlling a charging process of an energy storage device, or a control device integrated into an energy storage device. Such a device can receive or send raw data, i.e., measurement data, and/or parameters of a charging/discharging process or a history of charging/discharging processes via the interface. For example, the raw data, i.e., measurement data, and/or parameters and/or a history of these data and/or parameters from past charging/discharging processes can be stored in the memory.

The methods can preferably be computer-based, i.e., computer-implemented.

Although the invention has been shown and described with reference to certain preferred exemplary embodiments, equivalents and modifications will be carried out by those skilled in the art after reading and understanding the specification. The present invention includes all such equivalents and modifications and is limited only by the scope of the appended claims.

1. A method for determining a state of an energy storage device,
wherein the state of the energy storage device is determined iteratively in each case in successive iterations of a Kalman filter method based on a plurality of measured values of current and voltage of a charging or discharging process of the energy storage device,
wherein an error term in the process model or the measurement model of the Kalman filter method, which describes a process noise or measurement noise, is updated in each case in successive iterations of the Kalman filter method.

2. The method according to claim 1, wherein the error term of the Kalman filter method is determined using values of at least one parameter of a model of the Kalman filter method.

3. The method according to claim 1, wherein the error term of the Kalman filter method is determined using an uncertainty or uncertainties of the current and/or voltage of the charging or discharging process of the energy storage device.

4. The method according to claim 1, wherein the error term of the Kalman filter method is determined using uncertainties of values of at least one parameter of a model of the Kalman filter method.

5. The method according to claim 2, wherein at least one uncertainty of a parameter of the model is determined using an absolute value of at least one parameter of the model and/or at least one measured quantity of current and voltage.

6. The method according to claim 2,
wherein the model is a process model that determines a change of current and voltage of the energy storage as a function of the iterations based on an equivalent circuit model.

7. The method according to claim 2, wherein the at least one parameter is selected from a set comprising: quantization of time steps associated with the iterations of the Kalman filter method; time constant of an oscillating circuit of an equivalent circuit model of the energy storage device; resistance of an equivalent circuit model of the energy storage device; current flow in a previous iteration of the successive iterations; a capacity of the energy storage device; or current flow in a subsequent iteration of the successive iterations.

8. The method according to claim 1, wherein the error term of the process model is a covariance matrix that describes a cross-dependency of the uncertainties of process parameters of a plurality of parameters of a model of the Kalman filter method.

9. The method according to claim 8, wherein the uncertainties of the process parameters of the plurality of process parameters are modeled by probability distributions which are selected from: Gaussian normal distribution, uniform distribution, Weibull distribution.

10. A device for determining a state of an energy storage device, comprising a computing unit, a memory unit, an interface unit, wherein the memory unit stores commands executable by the computing unit, wherein the device is designed, when the commands are executed in the computing unit, to determine a state of the energy storage device in each of successive iterations of a Kalman filter method based on a plurality of measured values of current and voltage of a charging or discharging process of the energy storage device,
wherein an error term in the process model or the measurement model of the Kalman filter method, which describes a process noise or measurement noise, is updated in each case in successive iterations of the Kalman filter method.
